(19) United States
(12) Patent Application Publication
(10) Pub. No.: US 2024/0250059 A1
(43) Pub. Date: Jul. 25, 2024

(54) COMPLIANT CHUCK EDGE RING

(71) Applicant: Tokyo Electron Limited, Tokyo (JP)

(72) Inventors: Christopher NETZBAND, Albany, NY (US); Nathan IP, Austin, TX (US)

(21) Appl. No.: 18/530,067

(22) Filed: Dec. 5, 2023

Related U.S. Application Data
(60) Provisional application No. 63/440,271, filed on Jan. 20, 2023.

(51) Int. Cl. H01L 23/00

(52) U.S. Cl. CPC H01L 24/74; H01L 24/80; H01L 2224/74; H01L 2224/80894; H01L 2924/40

(57) ABSTRACT

An apparatus for handling a semiconductor wafer includes an upper wafer holder that has a front surface, and a compliant ring that is mounted around the upper wafer holder and has a front surface. The front surface of the compliant ring is flush with the front surface of the upper wafer holder and extends from the front surface of the upper wafer holder in a radial direction without extending beyond the front surface of the wafer holder in an axial direction. A method includes providing a first wafer with a bonding surface and back surface, the back surface of the wafer in contact with the front surfaces of the wafer holder and the compliant ring. The first wafer contacts a second wafer so a bond forms between the wafers in a radial direction, the compliant ring flexibly restricting the movement of the first wafer relative to the second wafer.

### CROSS-REFERENCE TO RELATED APPLICATION

This application claims priority to and the benefit of U.S. Provisional Application No. 63/440,271, filed Jan. 20, 2023, entitled “COMPLIANT CHUCK EDGE RING,” which is incorporated herein by reference in its entirety for all purposes.

### TECHNICAL FIELD

The present application relates generally to the field of apparatuses and methods for bonding semiconductor wafers.

### BACKGROUND

A bonding apparatus can be used to bond semiconductor wafers to each other for example by applying forces. The bonding apparatus may bring a center of a semiconductor wafer into contact with a center of another semiconductor wafer. Thereafter, the wafers are initially bonded to each other from their centers to their outer circumferential portions so that the bonded area expands outwards. Finally, the wafers are entirely bonded to each other. However, voids may be formed between the outer edge portions of the wafers, and can cause poor bonding, thereby leading to reduced reliability.

### SUMMARY

In a general aspect, an apparatus for handling a wafer includes an upper wafer holder having a front surface, and a compliant ring mounted around the upper wafer holder and having a front surface. The upper wafer holder front surface can be or include silicon oxynitride (SiOxNy), silicon oxycarbonitride (SiOCN), silicon carbonitride (SiCN), silicon nitride (SiN), silicon carbide (SiC), silicon dioxide (SiO2), alumina (Al203), or aluminum nitride (AlN). The front surface of the compliant ring is flush with and extends from the front surface of the upper wafer holder in a radial direction. The front surface of the upper wafer holder is configured to suck a primary surface of a first wafer, and an area of the front surface of the upper wafer holder is less than an area of the primary surface of the first wafer.

In some embodiments, the front surface of the compliant ring is configured to extend in the radial direction beyond the primary surface of the first wafer, and an area of a combined surface of the front surfaces of the upper wafer holder and the compliant ring is greater than the area of the primary surface of the first wafer. In other embodiments, an area of the combined surface of the front surfaces of the upper wafer holder and the compliant ring is identical to the area of the primary surface of the first wafer. In some embodiments, the compliant ring includes a polymer. The polymer includes polydimethylsiloxane (PDMS), Polyether ether ketone (PEEK), polyimide (PI), polyether imide (PEI), polymethylmethacrylate (PMMA), polyamide (PA), polyamide imide (PAI), polybutylene terephthalate (PBTP), or liquid crystal polymers both with or without filler additives such as glass or carbon fibers to modulate the compliance, or combination thereof. The compliant ring is more compliant than the upper wafer holder. In some embodiments, the compliant ring extends at least 2.00 mm from an edge of the upper wafer holder in the radial direction. In other embodiments, the compliant ring extends at least 2.25 mm from an edge of the upper wafer holder in the radial direction.

In another general aspect, an apparatus for handling a wafer includes an upper wafer holder having a front surface configured to hold a first wafer, a compliant ring mounted around the upper wafer holder and having a front surface, and a bottom wafer holder having a front surface configured to hold a second wafer. The front surface of the compliant ring is flush with and extends from the front surface of the upper wafer holder in a radial direction. The front surface of the upper wafer holder is configured to suck a primary surface of the first wafer. An area of the front surface of the upper wafer holder is less than an area of the primary surface of the first wafer, and an area of a combined surface of the front surfaces of the upper wafer holder and the compliant ring is greater than the area of the primary surface of the first wafer.

In some embodiments, the upper wafer holder includes a first vacuum-assisted chuck, and the bottom wafer holder includes a second vacuum-assisted chuck. In some embodiments, the upper wafer holder is configured to move the first wafer in the vertical direction towards the bottom wafer holder to bond the first and the second wafers. In other embodiments, the bottom wafer holder is configured to move the second wafer in the vertical direction towards the upper wafer holder to bond the first and the second wafers. In some embodiments, an area of the front surface of the upper wafer holder is less than an area of the front surface of the bottom wafer holder, and an area of a combined surface of the front surfaces of the upper wafer holder and the compliant ring is greater than or the same as the area of the front surface of the bottom wafer holder.

In yet another general aspect, a method includes providing a wafer holder having a front surface; providing a compliant ring around the wafer holder and having a front surface, in which the front surface of the compliant ring is in flush with and extends from the front surface of the wafer holder in a radial direction; providing a first wafer having a primary surface and a bonding surface, in which the primary surface of the wafer is configured to contact with the front surfaces of the wafer holder and the compliant ring; and contacting the bonding surface of the first wafer with a second wafer to form a bond between the first and second wafer.

In some embodiments, the compliant ring flexibly restricts a relative movement between the first and the second wafers. The wafer holder and the compliant ring are moved towards the second wafer in a vertical direction to form the bond between the first and the second wafers. The bond between the first and the second wafers is initially formed in a central region between the first and the second wafers, and then is propagated in a radial direction to a radical edge region between the first and the second wafers to reduce edge voids formed in the radical edge region.

Implementations of the described techniques may include hardware, a method or process, or a computer tangible medium for performing the process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a bonding apparatus.

FIG. 1B is a cross-sectional view illustrating the bonding apparatus as shown in FIG. 1A and operations of bonding two wafers using this bonding apparatus.

FIG. 2A illustrates a top view and a cross-sectional view of a bonding apparatus having a compliant ring, according to some embodiments.

FIG. 2B illustrates operations of bonding wafers using the bonding apparatus as shown in FIG. 2A, according to some embodiments.

FIG. 3 is a flowchart illustrating a method of bonding two wafers using a bonding apparatus as shown in FIGS. 2A and 2B, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element or feature as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

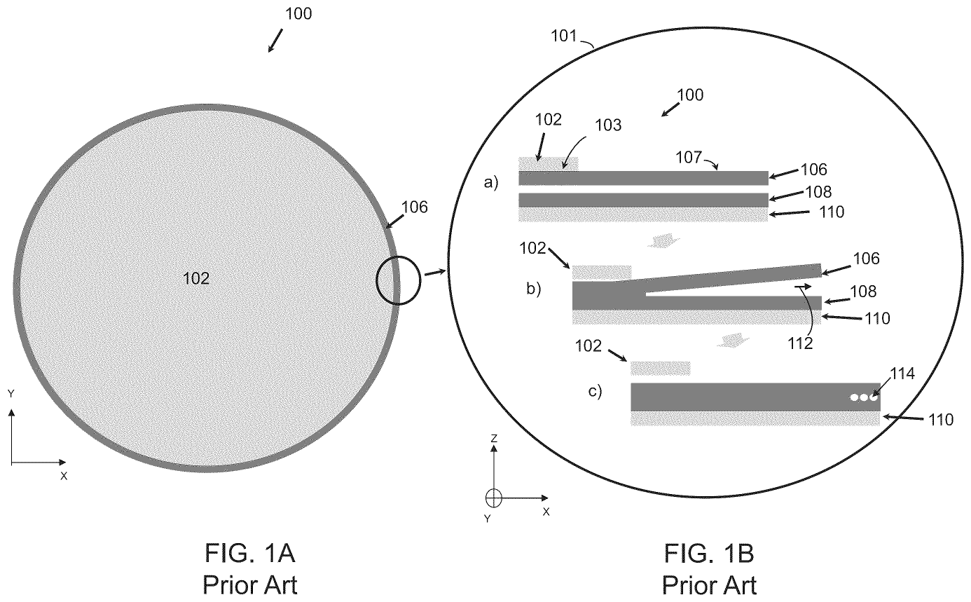

FIG. 1A is a top view of a bonding apparatus 100 according to some embodiments. FIG. 1B is a cross-sectional view (a bubble) 101 illustrating the bonding apparatus 100 as shown in FIG. 1A and operations of bonding two wafers using the bonding apparatus 100 according to some embodiments. The bubble 101 in FIG. 1B shows an expanded view of a side profile of the apparatus 100 at an edge region of two wafers, and various operations, such as a), b) and c), performed by the bonding apparatus 100 to form a bond between the wafers. Some features of the bonding apparatus 100 are not shown for the sake of simplicity.

Referring to FIGS. 1A and 1B, the bonding apparatus 100 includes an upper wafer holder 102 having a front surface 103 configured to hold a first wafer 106 having a primary surface 107, and a bottom wafer holder 110 configured to hold a second wafer 108. In some embodiments, the upper wafer holder 102 is implemented as an upper chuck, and the bottom wafer holder 110 is implemented as a bottom chuck. The area of the front surface 103 of the wafer holder 102 is less than the area of the primary surface 107 of the first wafer 106, so that the primary surface 107 of the first wafer 106 extends beyond (or past) the front surface 103 of the wafer holder 102 in a radical direction 112 in a horizontal plane.

Some operations for forming a bond between two wafers 106 and 108 are shown in FIG. 1B. As shown in operation a) of FIG. 1B, the upper wafer holder 102 holds the first wafer 106, and the bottom wafer holder 110 holds the second wafer 108. As shown in operation b) of FIG. 1B, the upper wafer holder 102 is configured to move the first wafer 106 in a vertical direction towards the bottom chuck 110 to bring the first wafer 106 into contact with the second wafer 108, thereby forming a bond between them. Then the bond is propagated through a bond wave propagation process along the radial direction 112.

However, because the area of the front surface 103 of the upper wafer holder 102 is smaller than the area of the primary surface 107 of the first wafer 106, the outer edge region of the first wafer 106 is unrestricted and thus can flex, thereby leading to decreased stress in the bond interface of the outer edge region. As shown in operation c) of FIG. 1B, upon the bond wave propagating through the unrestricted edges of the first wafer 106, edge voids 114 occur at the bond interface with decreased stress.

In some embodiments, a gas such as helium (He) is provided at the outer edge region to mitigate these edge voids. However, using the gas may not be ideal as the gas may not be readily available, may be dangerous, and may be difficult to supply and store. Also, the delivery system may be complex and expensive to implement and maintain. As such, a better way to mitigate edge voids is desired.

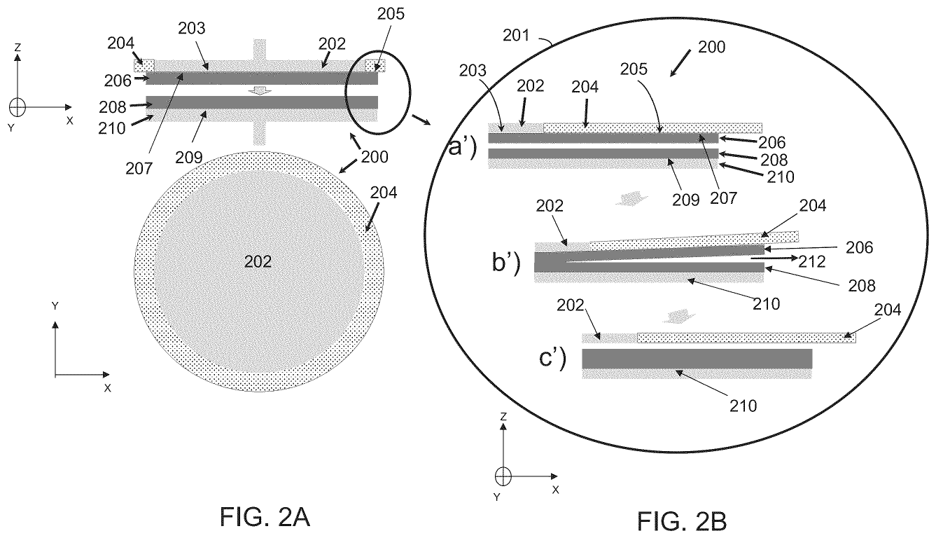

FIG. 2A illustrates a top view and a cross-sectional view of a bonding apparatus 200 having a compliant ring 204 according to some embodiments. FIG. 2B illustrates operations of bonding two wafers using the bonding apparatus 200 as shown in FIG. 2A according to some embodiments. The cross-sectional view (the bubble) 201 in FIG. 2B shows an expanded view of a side profile of the apparatus 200 at an edge region of two wafers, and various operations, such as a′), b′) and c′), performed by the bonding apparatus 200 to form a bond between the wafers. Some features (such as vacuum ports, plungers, and guides) of the bonding apparatus 200 are not shown for the sake of simplicity.

As shown in FIGS. 2A and 2B, in some embodiments, the bonding apparatus 200 includes an upper wafer holder 202 having a front surface 203, and a compliant ring 204 mounted around the wafer holder 202 and having a front surface 205. The front surface 205 of the compliant ring 204 extends along the front surface 203 of the wafer holder 202 in a radial direction (e.g., X direction) without extending beyond the front surface 203 of the wafer holder 202 in an axial direction (e.g., Z direction). The front surface 205 of the compliant ring 204 is flush with the front surface 203 of the wafer holder 202 in the radial direction.

In some embodiments, the front surface 203 of the upper wafer holder 202 is configured to suck and handle a first wafer 206 having a primary (e.g., upper) surface 207. The surface area of the front surface 203 of the wafer holder 202 is less than the primary surface 207 of the first wafer 206. In some embodiments, as shown in FIGS. 2B and 2C, the front surface 205 of the compliant ring 204 extends along the front surface 203 of the upper wafer holder 202 and beyond (or past) the primary surface 207 of the first wafer 206, and thus a combined front surface area of the upper wafer holder 202 and the compliant ring 204 is larger than the area of the primary surface 207 of the first wafer 206. In other embodiments, the front surface 205 of the compliant ring 204 extends along the front surface 203 of the upper wafer holder 202 until reaching an edge of the primary surface 207 of the first wafer 206, and thus a combined front surface area of the upper wafer holder 202 and the compliant ring 204 is the same as the area of the primary surface 207 of the first wafer 206.

In some embodiments, the compliant ring 204 is made of a polymer that is compliant, flexible, or compressible. In some embodiments, the polymer includes polydimethylsiloxane (PDMS). In some embodiments, the compliant ring 204 extends at least 2.0 mm from an edge of the upper wafer holder 202 in the radial direction 212. In other embodiments, the compliant ring 204 extends at least 2.2 mm from an edge of the upper wafer holder 202 in the radial direction 212.

In some embodiments, the upper wafer holder 202 is implemented as a vacuum-assisted chuck configured to suck and handle the first wafer 206 in the vertical (or Z-direction). In some embodiments, the first wafer 206 has a surface area greater than the vacuum-assisted chuck 202, but less than a combined front surface area of the vacuum assisted chuck 202 and compliant ring 204.

In some embodiments, the bonding apparatus 200 further includes a bottom wafer holder 210 having a front surface 209 configured to contact and handle a second wafer 208. The area of the front surface 209 of the bottom wafer holder 210 is larger than the area of the front surface 203 of the upper wafer holder 202. In some embodiments, the area of the front surface 209 of the bottom wafer holder 210 is less than the combined front surface area of the upper wafer holder 202 and the compliant ring 204. In other embodiments, the area of the front surface 209 of the bottom wafer holder 210 is the same as the combined front surface area of the upper wafer holder 202 and the compliant ring 204.

Some operations for forming a bond between wafers 206 and 208 are shown in FIG. 2B. As shown in operation a′) of FIG. 2B, an upper wafer holder 202 having a front surface 203 and a compliant ring 204 mounted around the upper wafer holder 202 are provided to hold and handle a first wafer 206. The compliant ring 204 has a front surface 205 that extends from the front surface 203 of the upper wafer holder 202 in a radial direction (e.g., X-direction) without extending beyond the front surface 203 of the upper wafer holder 202 in an axial direction (Z-direction). The front surface 205 of the compliant ring 204 is flush with the front surface 203 of the upper wafer holder 202 in the radial direction. The first wafer 206 has a bonding surface configured to bond with another wafer, and a primary surface 207 configured to be in contact with the front surfaces (203/205) of the upper wafer holder 202 and the compliant ring 204.

As shown in operation b′) of FIG. 2B, the bonding surface of the first wafer 206 is in contact with a bonding surface of a second wafer 208 in a central region thereof, such that a bond forms between the first wafer 206 and the second wafer 208 in the central region thereof, and propagates in a radial direction (e.g., X-direction) 212 to the edge regions thereof. The compliant ring 204 restricts movements of the first wafer 206 relative to the second wafer 208, though allowing some movement of the first wafer 206 to mitigate stress.

In some embodiments, the upper wafer holder 202 and the compliant ring 204 are moved in a vertical direction (e.g., Z-direction) so that the first wafer 206 is moved relative to the second wafer 208 in order to bond the first wafer 206 and the second wafer 208. The bond between the first wafer 206 and the second wafer 208 initially forms in a central region thereof, and then propagates radially outwards to an edge region thereof as the bond wave propagation process.

As a result, as shown in operation c′) of FIG. 2B, a bonded structure of the first wafer 206 and the second wafer 208 is formed with no voids or less voids in a radial edge region between the first wafer 206 and the second wafer 208. The compliant ring 204, among other things, functions or helps to avoid or reduce edge voids (e.g., 114 as shown in FIG. 1B) formed in the radial edge region, thereby improving reliability of the bonding between the wafers.

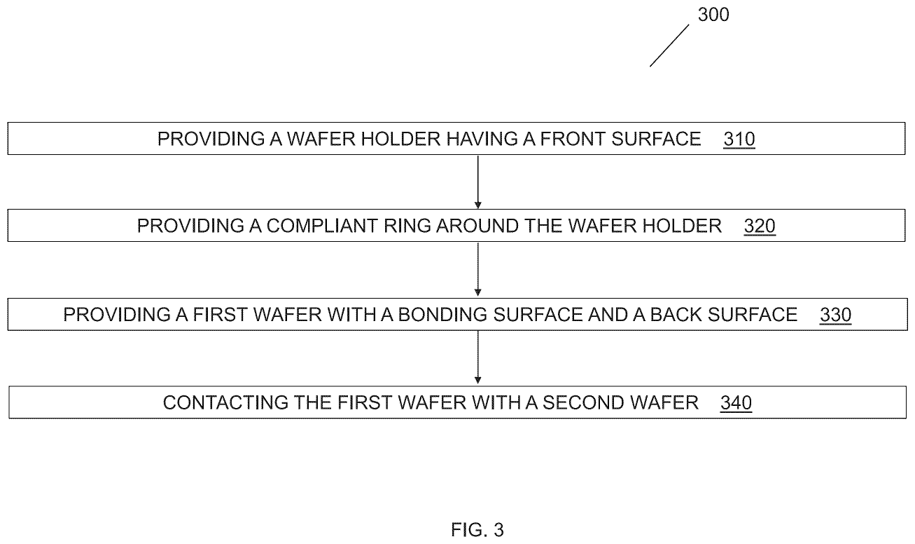

FIG. 3 is a flowchart illustrating a method of bonding two wafers using a bonding apparatus 200 as shown in FIGS. 2A and 2B according to some embodiments. It is understood that additional operations can be provided before, during, and after processes discussed in FIG. 3, and some of the operations described below can be replaced or eliminated, for additional embodiments of the method. The order of the operations/processes may be interchangeable and at least some of the operations or processes may be performed in a different sequence.

As shown in FIGS. 2A-2B and 3, in operation 310, an upper wafer holder 202 having a front surface 203 is provided. In operation 320, a compliant ring 204 mounted around the upper wafer holder 202 and having a front surface 205 is provided. In some embodiments, the front surface 205 of the compliant ring 204 is in flush with and extends from the front surface 203 of the upper wafer holder 202 in a radial direction (X-direction).

In operation 330, a first wafer 206 having a primary surface 207 and a bonding surface is provided. Additionally, a second wafer 208 having a primary surface 209 and a bonding surface is also provided. In some embodiments, the primary surface 207 of the first wafer 206 is configured to contact with the front surfaces 203/205 of the upper wafer holder 202 and the compliant ring 204. In some embodiments, the primary surface 209 of the second wafer 208 is configured to contact with the front surface of the bottom wafer holder.

In operation 340, the bonding surface of the first wafer 206 contacts with the bonding surface of a second wafer 208 so that a bond is formed between the first wafer 206 and the second wafer 208. In some embodiments, the upper wafer holder 202 and the compliant ring 204 are moved relative to the bottom wafer holder 210 in a vertical direction (Z-direction) to lead to a contact between the first wafer 206 and the second wafer 208, and thus form the bond between them. In some embodiments, the bond between the first wafer 206 and the second wafer 208 initially forms in a central region between them, and then propagates in a radial direction to a radical edge region between them. In some embodiments, the compliant ring 204 flexibly restricts a relative movement between the first wafer 206 and the second wafer 208, and thus avoids or reduces edge voids formed in the radical edge region, thereby leading to improved bonding reliability.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims 1-20 and their equivalents, in which all terms are meant in their broadest reasonable sense unless otherwise indicated.

1. An apparatus for handling a wafer, comprising:
an upper wafer holder having a front surface; and
a compliant ring mounted around the upper wafer holder and having a front surface, wherein the front surface of the compliant ring is flush with and extends from the front surface of the upper wafer holder in a radial direction.

2. The apparatus of claim 1, wherein the front surface of the upper wafer holder is configured to suck a primary surface of a first wafer, and wherein an area of the front surface of the upper wafer holder is less than an area of the primary surface of the first wafer.

3. The apparatus of claim 2, wherein the front surface of the compliant ring is configured to extend in the radial direction beyond the primary surface of the first wafer, and wherein an area of a combined surface of the front surfaces of the upper wafer holder and the compliant ring is greater than the area of the primary surface of the first wafer.

4. The apparatus of claim 2, wherein an area of a combined surface of the front surfaces of the upper wafer holder and the compliant ring is identical to the area of the primary surface of the first wafer.

5. The apparatus of claim 1, wherein the compliant ring comprises a polymer.

6. The apparatus of claim 1, wherein the compliant ring comprises polydimethylsiloxane (PDMS).

7. The apparatus of claim 1, wherein the compliant ring extends at least 2.00 mm from an edge of the upper wafer holder in the radial direction.

8. The apparatus of claim 1, wherein the compliant ring extends at least 2.25 mm from an edge of the upper wafer holder in the radial direction.

9. The apparatus of claim 1, wherein the compliant ring is more compliant than the upper wafer holder.

10. An apparatus for handling a wafer, comprising:
an upper wafer holder having a front surface configured to hold a first wafer;
a compliant ring mounted around the upper wafer holder and having a front surface, wherein the front surface of the compliant ring is flush with and extends from the front surface of the upper wafer holder in a radial direction; and
a bottom wafer holder having a front surface configured to hold a second wafer.

11. The apparatus of claim 10, wherein the front surface of the upper wafer holder is configured to suck a primary surface of the first wafer, and wherein an area of the front surface of the upper wafer holder is less than an area of the primary surface of the first wafer.

12. The apparatus of claim 11, wherein an area of a combined surface of the front surfaces of the upper wafer holder and the compliant ring is greater than the area of the primary surface of the first wafer.

13. The apparatus of claim 11, wherein the upper wafer holder comprises a first vacuum-assisted chuck, and wherein the bottom wafer holder comprises a second vacuum-assisted chuck.

14. The apparatus of claim 13, wherein the upper wafer holder is configured to move the first wafer in the vertical direction relative to the bottom wafer holder to bond the first wafer and the second wafer.

15. The apparatus of claim 13, wherein the bottom wafer holder is configured to move the second wafer in the vertical direction relative to the upper wafer holder to bond the first wafer and the second wafer.

16. The apparatus of claim 10, wherein an area of the front surface of the upper wafer holder is less than an area of the front surface of the bottom wafer holder, and wherein an area of a combined surface of the front surfaces of the upper wafer holder and the compliant ring is greater than the area of the front surface of the bottom wafer holder.

17. A method comprising:
providing a wafer holder having a front surface;
providing a compliant ring around the wafer holder and having a front surface, wherein the front surface of the compliant ring is in flush with and extends from the front surface of the wafer holder in a radial direction;
providing a first wafer having a primary surface and a bonding surface, wherein the primary surface of the first wafer is configured to contact with the front surfaces of the wafer holder and the compliant ring; and
contacting the bonding surface of the first wafer with a second wafer to form a bond between the first and second wafer.

18. The method of claim 17, wherein the compliant ring flexibly restricts a relative movement between the first wafer and the second wafer.

19. The method of claim 17, wherein the wafer holder and the compliant ring are moved relative to the second wafer in a vertical direction to form the bond between the first wafer and the second wafer.

20. The method of claim 17, wherein the bond between the first wafer and the second wafer is initially formed in a central region between the first wafer and the second wafer, and is propagated in a radial direction to a radical radial edge region between the first wafer and the second wafer to reduce edge voids formed in the radical radial edge region.
